(19) United States
(12) Patent Application Publication
(10) Pub. No.: US 2026/0365034 A1
(43) Pub. Date: Nov. 19, 2026

(54) Traction Inverter System For Electric Vehicle

(71) Applicant: Rivian IP Holdings, LLC, Irvine, CA (US)

(72) Inventors: Seunghoon JEONG, Carson, CA (US); Thomas Hahn KIM, Boise, ID (US); Young DOO, La Palma, CA (US)

(21) Appl. No.: 19/675,222

(22) Filed: May 12, 2026

Related U.S. Application Data
(60) Provisional application No. 63/805,862, filed on May 14, 2025.

(51) Int. Cl. B60L 15/00; B60K 1/00; B60L 50/51; B60L 50/60; H02M 7/00; H05K 7/20

(52) U.S. Cl. CPC B60L 15/007; B60K 1/00; B60L 50/51; B60L 50/60; H02M 7/003; H05K 7/209; B60K 2001/006; B60L 2210/42; B60L 2240/425; B60L 2240/525

(57) ABSTRACT

In certain embodiments, a traction inverter system comprises a chassis, a cold plate attached to the chassis, power modules, and a cover attached to a perimeter of the chassis. The chassis is configured to be attached to a housing of an electric motor with a rotational axis. The cold plate comprises a first side and a second side, and the first side comprises sintering interface regions. The power modules are sintered to the sintering interface regions, and are coupled to the electric motor. The rotational axis is perpendicular to a plane defined by the perimeter of the chassis.

### CROSS-REFERENCE TO RELATED APPLICATIONS

This application claims the benefit of U.S. Provisional Application Serial No. 63/805,862 (filed on May 14, 2025), the content of which is incorporated by reference herein in its entirety.

### INTRODUCTION

The present disclosure relates to electric vehicles (EVs). More particularly, the present disclosure relates to a traction inverter system for an electric vehicle.

### SUMMARY

In certain embodiments, a traction inverter system comprises a chassis, a cold plate attached to the chassis, power modules, and a cover attached to a perimeter of the chassis. The chassis is configured to be attached to a housing of an electric motor with a rotational axis. The cold plate comprises a first side and a second side, and the first side comprises one or more sintering interface regions. The power modules are sintered to the sintering interface regions, and are coupled to the electric motor. The rotational axis is perpendicular to a plane defined by the perimeter of the chassis.

### BRIEF DESCRIPTION OF THE DRAWINGS

FIG. 1 depicts a diagram of an example electric vehicle (EV), in accordance with embodiments of the present disclosure.

FIG. 2 presents a block diagram of example components of an EV, in accordance with embodiments of the present disclosure.

FIG. 3A presents a diagram of example components of a control system for an EV, in accordance with embodiments of the present disclosure.

FIG. 3B presents a diagram of example components of a control system zone for an EV, in accordance with embodiments of the present disclosure.

FIG. 3C presents a diagram of example components of another control system zone for an EV, in accordance with embodiments of the present disclosure.

FIG. 3D presents a diagram of example components of another control system zone for an EV, in accordance with embodiments of the present disclosure.

FIG. 4 presents a perspective view of an example single motor electric drive unit, in accordance with embodiments of the present disclosure.

FIG. 5A presents a perspective left side view of an example traction inverter with the cover removed, in accordance with embodiments of the present disclosure.

FIG. 5B presents a perspective right side view of the example traction inverter with the cover removed, in accordance with embodiments of the present disclosure.

FIG. 6A presents a right side view of the example traction inverter with the cover removed, in accordance with embodiments of the present disclosure.

FIG. 6B presents a right side view of the example traction inverter with the cover and certain components removed, in accordance with embodiments of the present disclosure.

FIG. 6C presents a right side view of the example traction inverter with the cover and additional components removed, in accordance with embodiments of the present disclosure.

FIG. 7A presents a right side view of a cold plate of the example traction inverter, in accordance with embodiments of the present disclosure.

FIG. 7B presents a left side view of the cold plate of the example traction inverter, in accordance with embodiments of the present disclosure.

FIG. 7C presents a perspective right side view of the cold plate of the example traction inverter, in accordance with embodiments of the present disclosure.

FIG. 7D presents a perspective left side view of the cold plate of the example traction inverter, in accordance with embodiments of the present disclosure.

### DETAILED DESCRIPTION

Generally, a single motor electric drive unit (EDU) for an electric vehicle includes, inter alia, an AC electric motor, a gearbox, and a traction inverter. The gearbox is mounted to one end of the AC electric motor housing, and couples the output drive shaft of the AC electric motor to a differential drive shaft for the front or rear wheels. The gearbox provides a single-speed transmission, and is also known as a fixed-ratio gearbox. The traction inverter is mounted to the upper surface of the AC electric motor housing, and converts DC power received from the battery to AC power to drive the AC electric motor. During regeneration, the traction inverter may convert AC power generated by the AC motor into DC power to recharge the battery.

The traction inverter includes, inter alia, a capacitor module, power modules (also known as power inverter modules or PIMs), and a controller board. The capacitor module (also known as a DC link capacitor) includes a bank of capacitors that stabilizes the DC voltage received from the battery to limit fluctuations when the inverters of the power modules intermittently demand a large (or heavy) DC current. Each power module generates one phase of the AC power provided to the AC electric motor, e.g., three power modules generate AC power for a three-phase AC electric motor. The controller board controls the power modules, and is coupled to the electric vehicle’s control system in order to receive motor control commands from, and transmit data to, one or more electronic control units (ECUs) of the electric vehicle.

Generally, the housing for the traction inverter has a box shape with a flat, lower surface, while the housing for the AC electric motor has a cylindrical shape with a curved surface and two ends. Accordingly, the upper surface of the AC electric motor housing has a flat portion that is configured to receive the flat, lower surface of the traction inverter housing. However, the dimensions of the combined AC electric motor and traction inverter (such as overall height, required volumetric envelope, etc.) present challenges and complications when the EDU is installed in multiple vehicle platforms with different vehicle packaging constraints, manufacturing requirements (such as assembly speed, automation capabilities, and overall efficiency, etc.), etc.

Embodiments of the present disclosure advantageously provide a traction inverter that, inter alia, reduces the overall height of the EDU, reduces the required volumetric envelope of the EDU, improves the electrical and thermal efficiency and performance of the EDU, and lowers cost. The traction inverter may also be known as a traction inverter system.

In various embodiments, advantageously, the traction inverter is mounted to the other end of the AC electric motor housing (e.g., the end without the gearbox), which reduces the overall height and the required volumetric envelope of the EDU. Additionally, the traction inverter provides a common overall height and the required volumetric envelope for front and rear EDUs, which provides flexibility in performance variations of the electric vehicle. Generally, the traction inverter better utilizes the limited packaging space available for the front and rear EDUs.

Advantageously, each power module is sintered to a cold plate within the traction inverter housing to improve the electrical and thermal performance of the traction inverter, and to reduce cost. The traction inverter may accommodate different types of power modules while maintaining standardized EDU electrical and thermal interfaces.

In certain embodiments, the AC electric motor is a 3-phase AC electric motor, and the traction inverter includes three, half-bridge power modules that replace and deliver improvements over the conventional traction inverter power modules. The half-bridge power modules may be flexibly packaged as discrete power modules or hybrid pack-style power modules. The half-bridge power modules improve power efficiency and reduce power consumption while maintaining or improving overall traction inverter system performance.

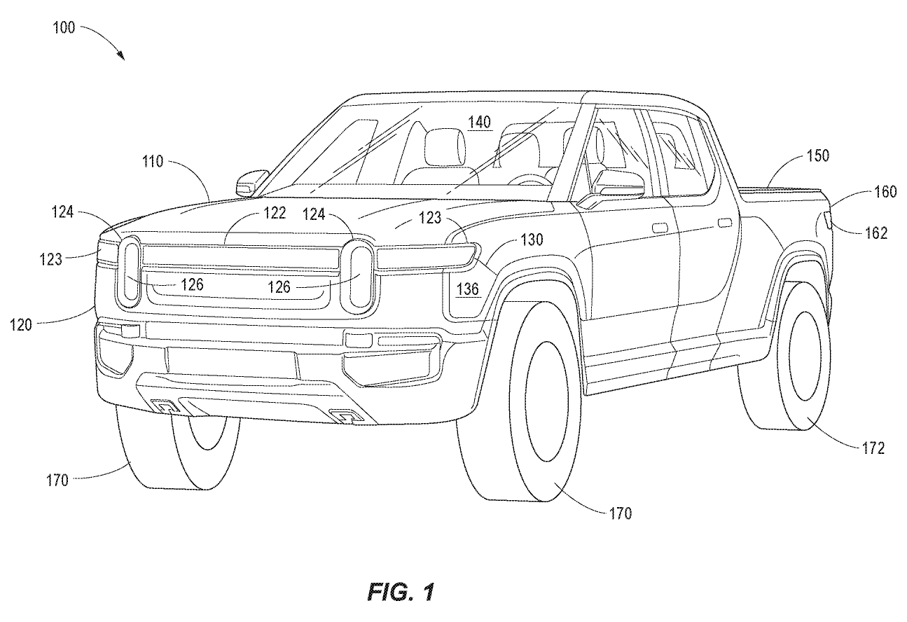

FIG. 1 depicts a diagram of an example electric vehicle 100, in accordance with embodiments of the present disclosure. While the electric vehicle 100 is used to discuss certain aspects of the present disclosure, the principles described herein may be applied to any type of vehicle with an information and entertainment (or infotainment) system.

Electric vehicle 100 includes, inter alia, a frame and body 110, an electrical power storage and distribution system, a propulsion system, a suspension system, a steering system, a control system, auxiliary and accessory systems (such as thermal management, lighting, wireless communications, navigation, etc.), etc.

Generally, body 110 may be directly or indirectly mounted to a frame (i.e., body-on-frame construction), or body 110 may be formed integrally with a frame (i.e., unibody construction). Body 110 includes, inter alia, front end 120, front light bar 122, front turn lights 123, stadium light rings 124, headlights 126, charging port 130 with charging port cover 136 concealing charging connector socket, driver/passenger compartment or cabin 140, bed 150, rear end 160 with rear taillights 162, a rear light bar, etc. Electric vehicle 100 may be a pickup truck, a sport utility vehicle (SUV) in which bed 150 is replaced by an extension of cabin 140, or a sedan in which bed 150 is replaced by a trunk. In certain embodiments, electric vehicle may be an electric delivery vehicle, an electric cargo van, etc.

The propulsion system may include, inter alia, one or more electronic control units (ECUs), one or more EDUs, front wheels 170, rear wheels 172, etc. The electrical power storage and distribution system may include, inter alia, one or more ECUs, a battery enclosure including a housing containing a battery (also known as a traction battery), a vehicle charging subsystem including charging port 130, a high voltage (HV) wiring harness (or battery cable) connecting the battery to the other HV electrical system components, such as the EDUs, etc.

A single motor EDU may be used to drive front wheels 170 (front wheel drive) or rear wheels 172 (rear wheel drive). Additionally, a single motor EDU may be used to drive front wheels 170 and a single motor EDU may be used to drive rear wheels 172 (four wheel drive). A dual motor EDU may be used to independently drive front wheels 170 (independent front wheel drive) or rear wheels 172 (independent rear wheel drive). Additionally a dual motor EDU may be used to independently drive both front wheels 170 and a dual motor EDU may be used to independently drive both rear wheels 172 (independent four wheel drive).

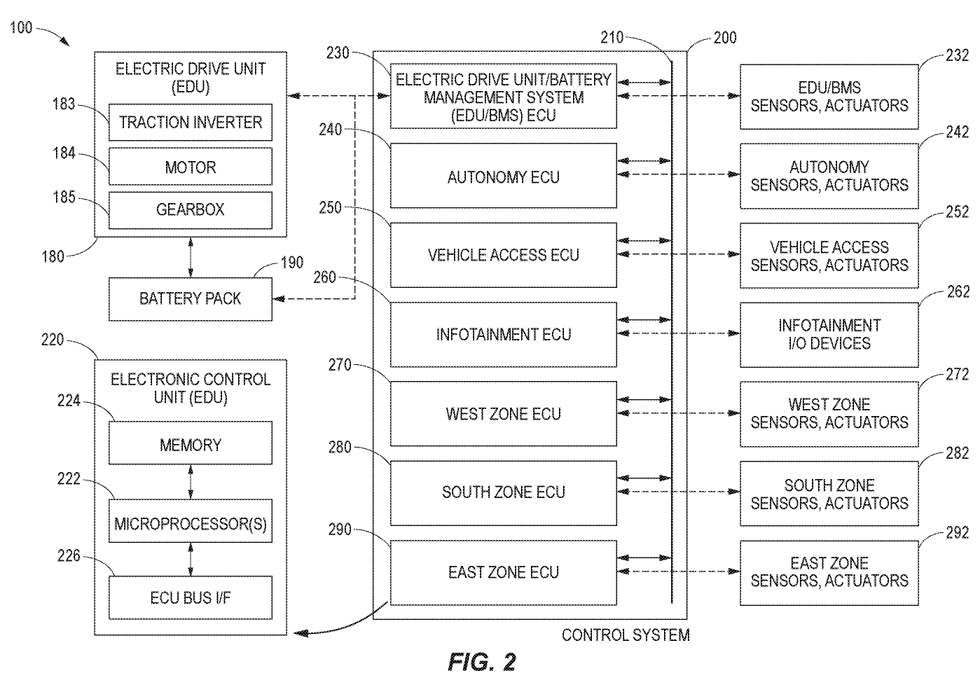

FIG. 2 presents a block diagram of example components of electric vehicle 100, in accordance with embodiments of the present disclosure.

Generally, electric vehicle 100 includes control system 200 that is configured to perform the functions necessary to operate electric vehicle 100. In certain embodiments, control system 200 includes a number of ECUs 220 coupled to ECU bus 210 (also known as a controller area network or CAN bus). Each ECU 220 performs a particular set of functions, and includes, inter alia, one or more processors 222 coupled to memory 224 and ECU bus interface (I/F) 226. Control system 200 may also include one or more wireless network interfaces to provide a wireless communications hub for electric vehicle 100, such as a Bluetooth (BT) or Bluetooth Low Energy (BLE) transmitter/receiver (or transceiver), a WiFi transceiver, a cellular network transceiver, etc.

Generally, control system 200 may be coupled to sensors (such as cameras, radar sensors, ultrasonic sensors, a global positioning system (GPS) receiver, etc.), actuators (such as electric, hydraulic, pneumatic, etc.), input/output (I/O) devices (such as displays, touchscreen displays, mechanical, electrical and electro-mechanical switches, etc.), as well as other components within the propulsion system, the electrical power storage and distribution system, the suspension system, the steering system, the auxiliary and accessory systems, etc., such as one or more EDUs 180, a battery 190, etc. Each EDU includes a traction inverter 183, a motor 184, and a gearbox 185.

Processor 222 may be a microcontroller unit, a microprocessing unit, a central processing unit (CPU), a programmable logic device (PLD), a complex PLD, a field programmable gate array (FPGA), an application specific integrated circuit (ASIC), etc. Memory 224 may include non-volatile and/or volatile memory, such as read only memory (ROM), random access memory (RAM), static RAM (SRAM), dynamic RAM (DRAM), flash memory, etc. In certain embodiments, control system 200 may include a number of system-on-chips (SoCs). Each SoC may include a number of multi-core processors coupled to a high-speed interconnect and on-chip memory that provide more robust functionality and performance than an ECU 220 with a single processor 222.

In certain embodiments, control system 200 may include an electric drive unit/battery management system (EDU/BMS) ECU 230, an autonomy ECU 240, a vehicle access ECU 250, an infotainment ECU 260, a west zone ECU 270, a south zone ECU 280, and an east zone ECU 290.

The EDU/BMS ECU 230 provides functionality related to the propulsion and electrical power storage and distribution system, and is coupled to EDU/BMS sensors and actuators 232. The autonomy ECU 240 provides functionality related to autonomous vehicle activities, such as sensor data processing, image recognition, etc., and is coupled to autonomous sensors and actuators 242, such as cameras, radars, etc. The vehicle access ECU 250 provides functionality related to accessing and securing the vehicle, such as wireless key fobs, a security system, etc., and is coupled to vehicle access sensors and actuators 252. The infotainment ECU 260 provides functionality related to presenting vehicle information and receiving commands to control the various subsystems (such as HVAC, lighting, etc.), as well as functionality related to various media sources, such as HD and satellite radio, and natively-integrated media provider applications. The infotainment ECU 260 is coupled to the infotainment sensors and actuators 262.

The west zone ECU 270, the south zone ECU 280, and the east zone ECU 290 are also known as zonal controllers, and each zonal controller may control a subset of the sensors and actuators of the electric vehicle 100. The subset of sensors and actuators controlled by each zonal controller may be generally assigned based on location within the electric vehicle 100. For example, the west zone ECU 270 may control the sensors and actuators on a driver side of the electric vehicle 100, the south zone ECU 280 may control the sensors and actuators in a rear portion of the electric vehicle 100, and the east zone ECU 290 may control the sensors and actuators on a passenger side of the electric vehicle 100.

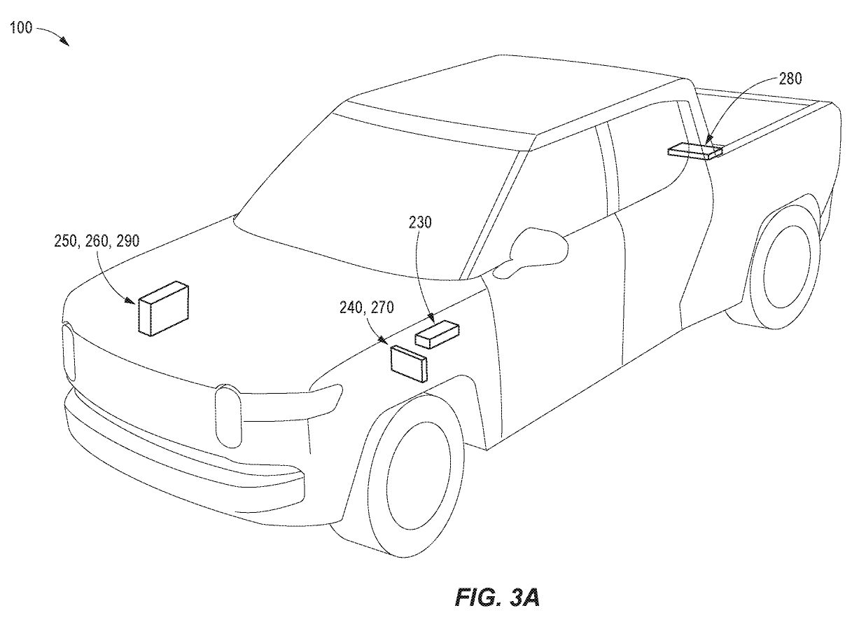

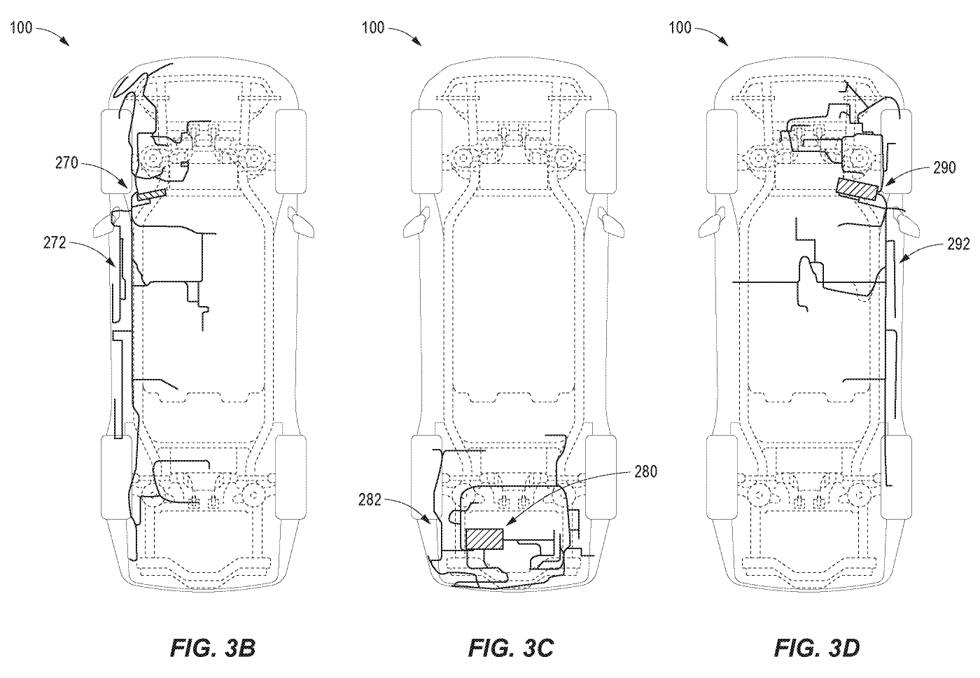

FIG. 3A presents a diagram of example components of the control system 200 for the electric vehicle 100, in accordance with embodiments of the present disclosure.

In certain embodiments, the EDU/BMS ECU 230, the autonomy ECU 240, the vehicle access ECU 250, the infotainment ECU 260, the west zone ECU 270, the south zone ECU 280, and the east zone ECU 290 may be arranged as depicted in FIG. 3A. Other locations for each ECU are also supported.

FIG. 3B presents a diagram of example components of a control system zone for the electric vehicle 100, in accordance with embodiments of the present disclosure.

In certain embodiments, the west zone may include the west zone ECU 270 and the west zone sensors and actuators 272, as depicted in FIG. 3B. Other locations and arrangements for the west zone ECU 270 and the west zone sensors and actuators 272 are also supported.

FIG. 3C presents a diagram of example components of another control system zone for the electric vehicle 100, in accordance with embodiments of the present disclosure.

In certain embodiments, the south zone may include the south zone ECU 280 and the south zone sensors and actuators 282, as depicted in FIG. 3C. Other locations and arrangements for the south zone ECU 280 and the south zone sensors and actuators 282 are also supported.

FIG. 3D presents a diagram of example components of another control system zone for the electric vehicle 100, in accordance with embodiments of the present disclosure.

In certain embodiments, the east zone may include the east zone ECU 290 and the east zone sensors and actuators 292, as depicted in FIG. 3D. Other locations and arrangements for the east zone ECU 290 and the east zone sensors and actuators 292 are also supported.

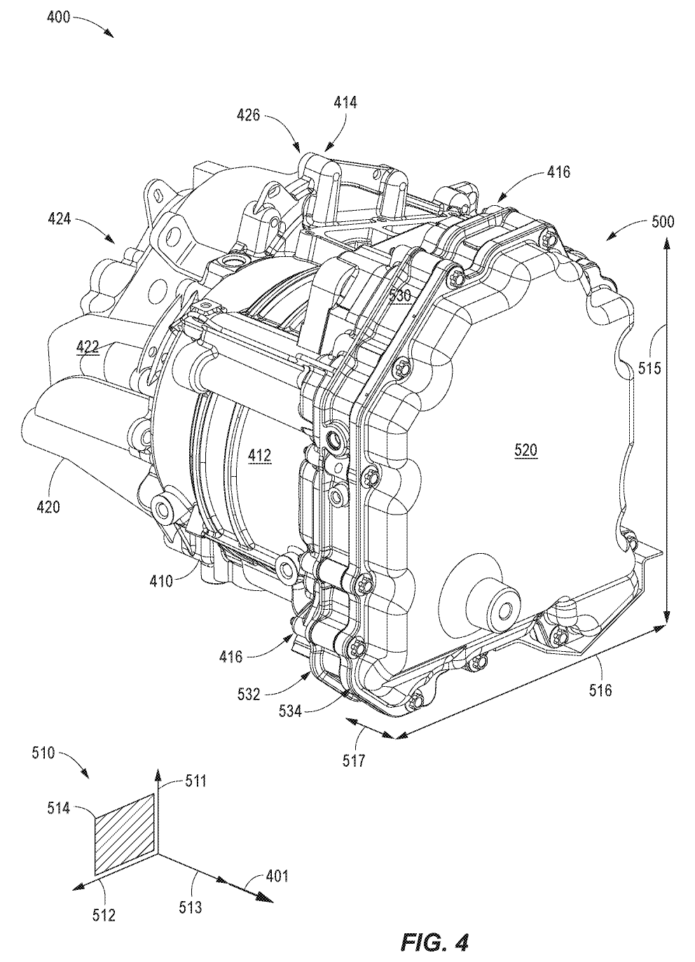

FIG. 4 presents a perspective view of a single motor EDU 400, in accordance with embodiments of the present disclosure.

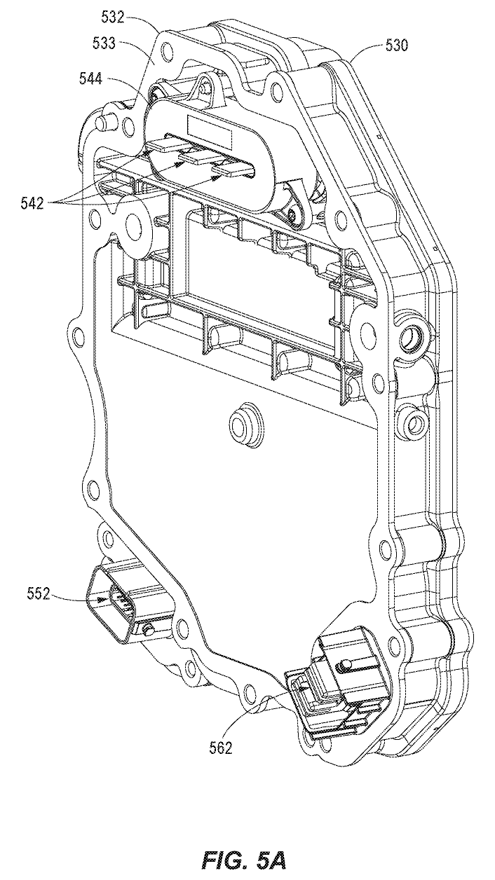

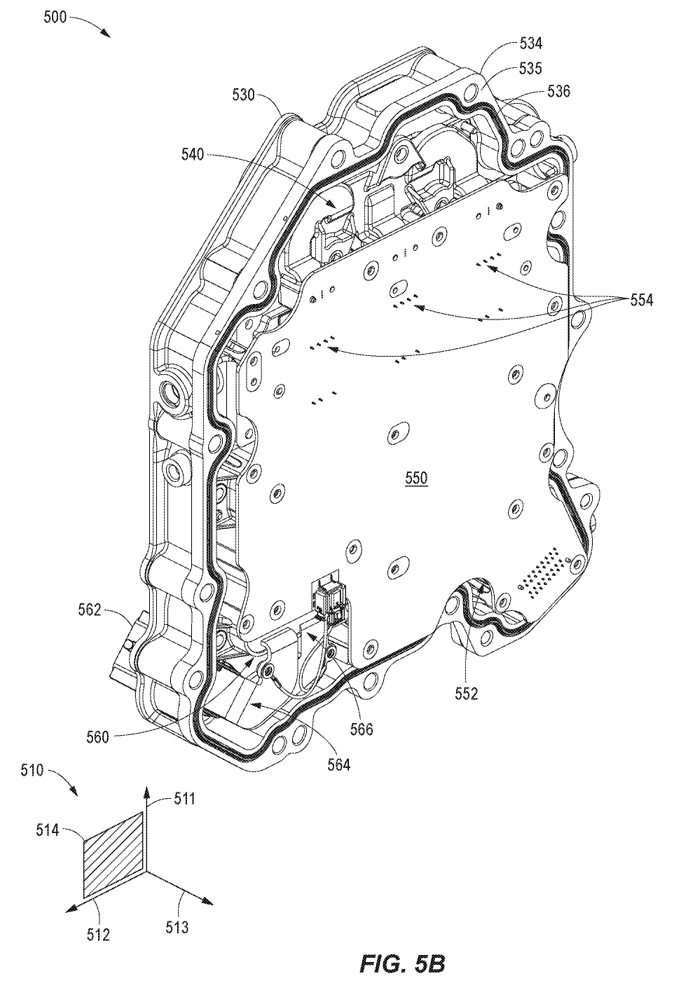

In certain embodiments, the EDU 400 includes an electric motor 410, a gearbox 420, and a traction inverter 500. The traction inverter 500 is discussed in more detail with respect to FIGS. 5A, 5B, 6A, 6B, 7C, 7A, 7B, 7C, 7D.

The electric motor 410 includes, inter alia, an AC electric motor and an electric motor housing 412. In various embodiments, the AC electric motor has a cylindrical shape. The electric motor housing 412 is generally cylindrical with curved sides, a first end 414 with a first interface surface, and a second end 416 with a second interface surface. The first interface surface of the first end 414 and the second interface surface of the second end 416 are generally flat and parallel to one another. The AC electric motor has an output drive shaft that is disposed proximate to the first end 414. The output drive shaft has a rotational axis 401 that is perpendicular to the first interface surface of the first end 414 and the second interface surface of the second end 416. In certain embodiments, the AC electric motor is a three phase AC electric motor, while in some embodiments, the AC electric motor is a single phase AC motor.

The gearbox 420 includes, inter alia, a single-speed transmission and a gearbox housing 422. The single-speed transmission couples the output drive shaft of the AC electric motor to a differential drive shaft for the front or rear wheels. In various embodiments, the gearbox housing 422 has generally curved sides, a closed first end 424, and a second end 426 with a generally flat interface surface. The interface surface of the second end 426 is mounted to the first interface surface of the first end 414 of the electric motor housing 412.

The traction inverter 500 includes, inter alia, power inverters, a capacitor module, a cover 520, and a chassis 530. The cover 520 and the chassis 530 are made of aluminum.

In various embodiments, the chassis 530 includes a first perimeter 532 and a second perimeter 534 (see FIGS. 5A and 5B, respectively). The first perimeter 532 has a first interface surface 533 (FIG. 5A) and the second perimeter 534 has a second interface surface 535 (FIG. 5B). The first interface surface 533 and the second interface surface 535 are generally flat and parallel to one another. The first interface surface 533 of the first perimeter 532 is mounted to the second interface surface of the second end 416 of the electric motor housing 412. The cover 520 is attached to the second interface surface 535 of the second perimeter 534.

An orthogonal coordinate system 510 for the traction inverter 500 may include a first axis 511, a second axis 512, and a third axis 513. The rotational axis 401 of the output drive shaft of the AC electric motor is parallel to the third axis 513 (as depicted). Generally, the traction inverter 500 may have a first dimension 515 along the first axis 511, a second dimension 516 along the second axis 512, and a third dimension 517 along the third axis 513. In certain embodiments, the first dimension 515 is larger than the second dimension 516, and the second dimension 516 is larger than the third dimension 517. In other embodiments, the second dimension 516 may be larger than the first dimension 515 (which is larger than the third dimension 517). Other dimensional relationships are also supported.

The second interface surface 535 of the second perimeter 534 defines the plane 514 that includes the first axis 511 and the second axis 512. It is noted that the first interface surface 533 of the first perimeter 532 may also define a plane that includes the first axis 511 and the second axis 512. Due to the orthogonality of the coordinate system 510, the third axis 513 is perpendicular to the plane 514. And, because the rotational axis 401 is parallel to the third axis 513, the rotational axis 401 is perpendicular to the plane 514 defined by second perimeter 534 of the chassis 530. In other words, the rotational axis is perpendicular to a plane defined by the perimeter of the chassis.

FIG. 5A presents a perspective left side view of the traction inverter 500 with the cover 520 removed, in accordance with embodiments of the present disclosure.

The chassis 530, the first perimeter 532, and the first interface surface 533 are depicted. The traction inverter 500 also includes, inter alia, an AC busbar 540 (FIG. 5B) with AC busbar terminals 542, a filter module 544, a low voltage (LV) electrical signal connector 552, and a high voltage (HV) wiring harness connector 562.

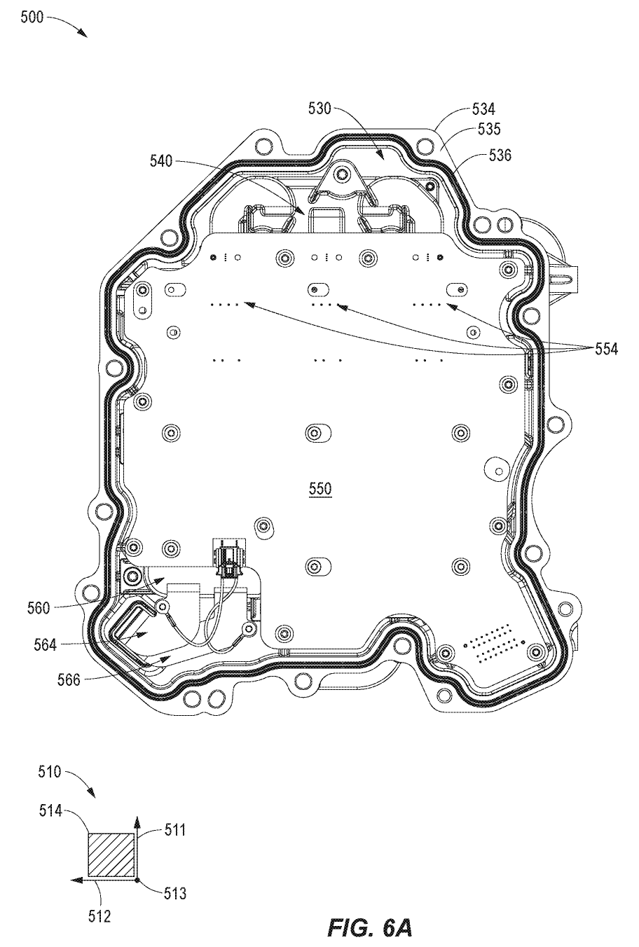

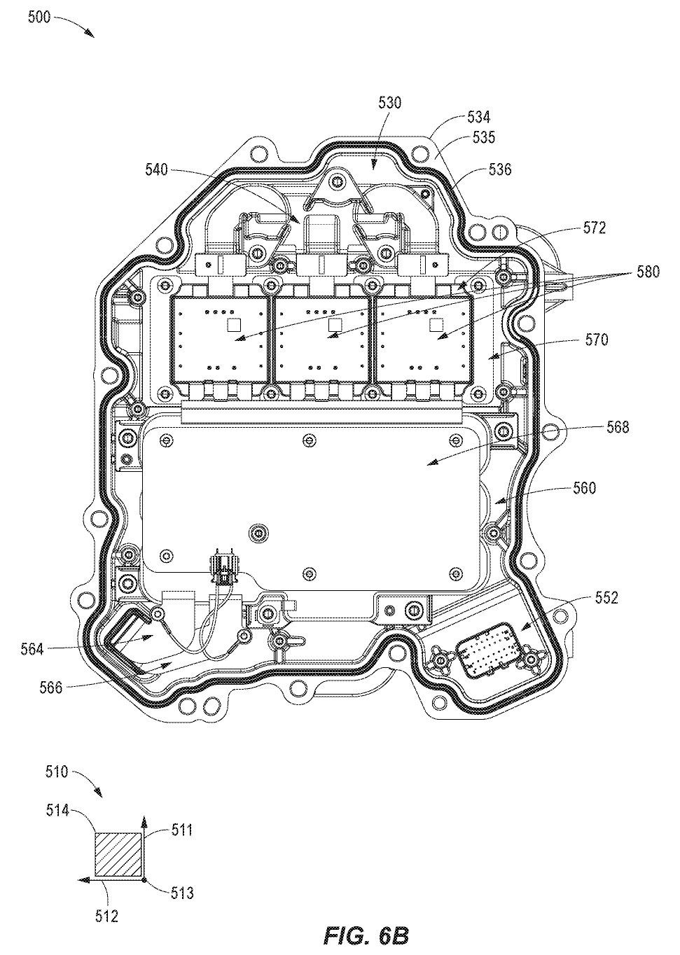

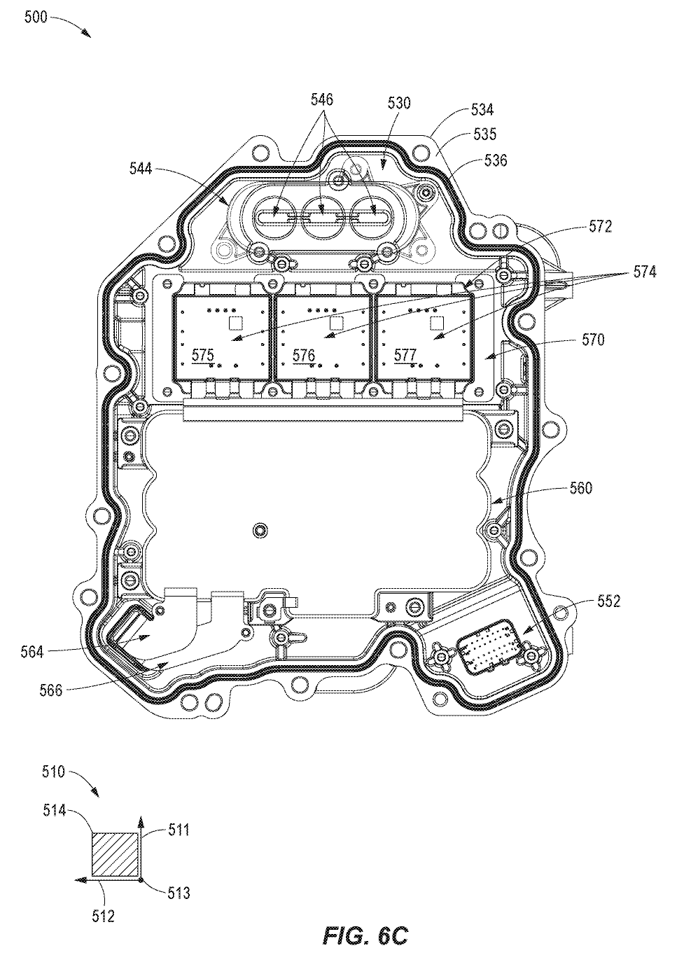

The AC busbar 540 is attached to the chassis 530, and couples the power modules 580 (see FIG. 6B) to the AC electric motor. The AC busbar 540 includes AC busbar terminals 542 that extend through the filter module 544 to mating connectors or sockets attached to the electric motor housing 412 to connect the power modules 580 to the AC electric motor. Each AC busbar terminal 542 couples one power module to one phase of the AC electric motor. The filter module 544 is attached to the chassis 530, and reduces or prevents unwanted noise transmission to the AC electric motor.

The LV electrical signal connector 552 is attached to the chassis 530, and may be connected to an LV wiring harness or electrical signal cable that is coupled to the control system 200 (such as the EDU/BMS ECU 230, etc.). The HV wiring harness connector 562 is attached to the chassis 530, and may be connected to the battery 190 via an HV wiring harness.

FIG. 5B presents a perspective right side view of the traction inverter 500 with the cover 520 removed, in accordance with embodiments of the present disclosure.

The chassis 530, the second perimeter 534, and the second interface surface 535, the AC busbar 540, and the orthogonal coordinate system 510 are depicted. The traction inverter 500 also includes, inter alia, a gasket 536, a controller board 550, a capacitor module 560, a positive HV voltage terminal 564, and a negative HV voltage terminal 566.

The gasket 536 is disposed along the second perimeter 534, and the cover 520 and the chassis 530 form an enclosed volume that is sealed by the gasket 536.

The controller board 550 is a printed circuit board assembly (PCBA), such as a gate driver PCBA, etc., that is attached to the chassis 530. The controller board 550 includes electrical connection interface/thru holes 554 that are coupled to the power modules 580 (see FIG. 6B). Generally, the controller board 550 controls the power modules 580 (see FIG. 6B) that generate the AC power (i.e., AC voltage and current) provided to the AC electric motor. The controller board 550 is connected to the LV electrical signal connector 552, and receives motor control commands from, and transmits data to, the control system 200 via the LV wiring harness or electrical signal cable.

The capacitor module 560 (also known as a DC capacitor or a DC link capacitor) includes a bank of capacitors that stabilizes the DC voltage received from the battery 190 to limit fluctuations when the power modules 580 (see FIG. 6B) intermittently demand a large (or heavy) DC current. The positive HV voltage terminal 564 and the negative HV voltage terminal 566 are connected to the capacitor module 560 and the HV wiring harness connector 562.

FIG. 6A presents a right side view of the traction inverter 500 with the cover 520 removed, in accordance with embodiments of the present disclosure.

The chassis 530, the second perimeter 534, the second interface surface 535, the gasket 536, the AC busbar 540, the controller board 550, the capacitor module 560, the positive HV voltage terminal 564, the negative HV voltage terminal 566, and the orthogonal coordinate system 510 are depicted.

FIG. 6B presents a right side view of the traction inverter 500 with the cover 520 and the controller board 550 removed, in accordance with embodiments of the present disclosure.

The chassis 530, the second perimeter 534, the second interface surface 535, the gasket 536, the AC busbar 540, the LV electrical signal connector 552, the capacitor module 560, the positive HV voltage terminal 564, the negative HV voltage terminal 566, the power modules 580, and the orthogonal coordinate system 510 are depicted. The traction inverter 500 also includes, inter alia, a shield bracket 568, a cold plate 570, and an electrical insulation region 572 surrounding the power modules 580.

The shield bracket 568 is attached to the capacitor module 560, and is disposed between the capacitor module 560 and the controller board 550.

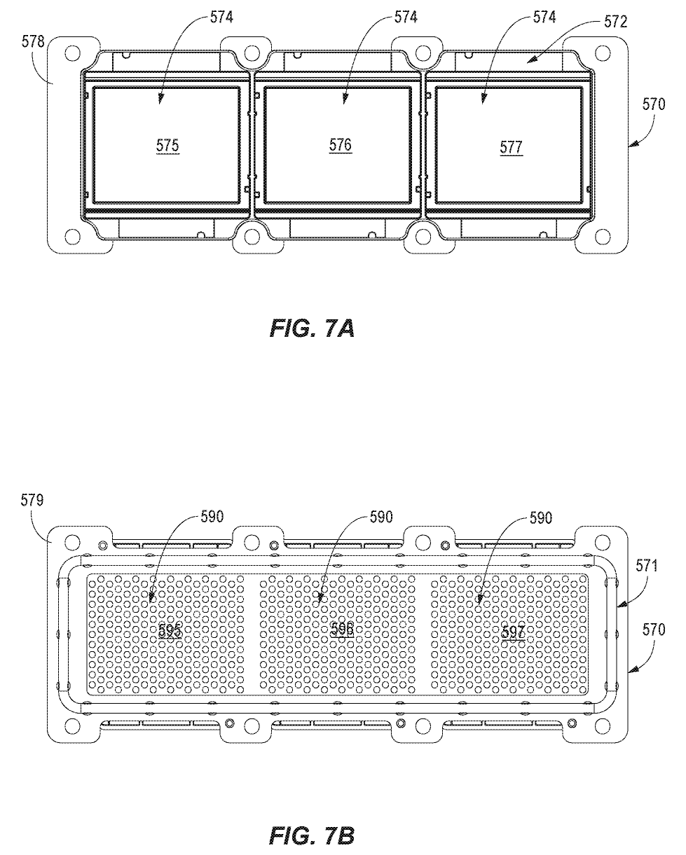

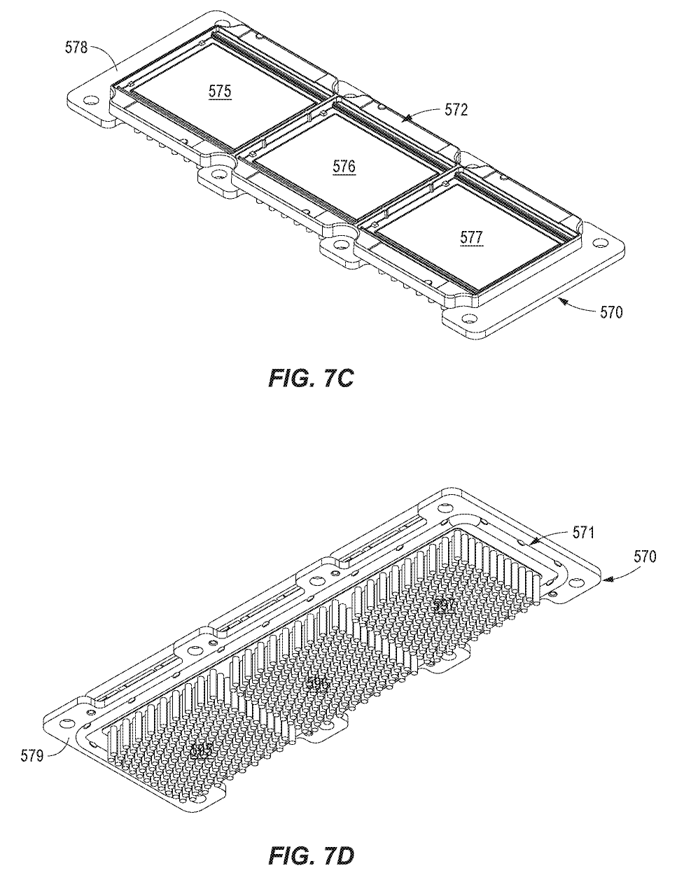

Generally, the cold plate 570 is a heat sink that removes heat from the power modules 580. The cold plate may be made from aluminum, copper, etc. The cold plate 570 is attached to the chassis 530 above a depression in a portion of the chassis 530. The cold plate 570 and the depression form a chamber that receives cooling fluid to cool the power modules 580 that are attached to the cold plate 570. A gasket 571 (see FIG. 7B, 7D) may be disposed on the cold plate 570 to seal the chamber. The chamber includes one or more fluid inlets and one or more fluid outlets that are coupled to the cooling system of the electric vehicle 100.

In certain embodiments, the power modules 580 may be half-bridge, silicon carbide (SiC) metal-oxide semiconductor field-effect transistor (MOSFET) power modules. Generally, SiC semiconductors improve overall system efficiency by allowing higher operating temperatures and switching frequencies. The power modules 580 are attached to the cold plate 570 by sintering. In some embodiments, the power modules 580 may be attached to the cold plate 570 using methods that provide similar heat transfer performance to sintering. In other embodiments, the power modules 580 may be soldered to the cold plate 570.

FIG. 6C presents a right side view of the traction inverter 500 with the cover 520, the AC busbar 540, the controller board 550, the shield bracket 568, the power modules 580 removed, in accordance with embodiments of the present disclosure.

The chassis 530, the second perimeter 534, the second interface surface 535, the gasket 536, the filter module 544, the LV electrical signal connector 552, the capacitor module 560, the positive HV voltage terminal 564, the negative HV voltage terminal 566, the cold plate 570, the electrical insulation region 572, and the orthogonal coordinate system 510 are depicted.

The filter module 544 includes passages 546 for the AC busbar terminals 542.

In certain embodiments, the cold plate 570 includes a region of sintering interface material 574 to which the power modules 580 are sintered using silver sintering paste. For example, the sintering interface material 574 may be arranged as sintering interface regions 575, 576, 577. Other types of sintering paste may also be used, such as copper sintering paste, etc. The sintering interface material 574 may be aluminum, copper, etc. In other embodiments, the power modules 580 may be sintered directly to the cold plate 570 using silver sintering paste.

FIGS. 7A and 7C present a right side view and a perspective right side view (respectively) of a cold plate 570 of the traction inverter 500, in accordance with embodiments of the present disclosure.

In certain embodiments, the cold plate 570 includes sintering interface regions 575, 576, 577 disposed on a first side 578 to which the power modules 580 are sintered. The electrical insulation region 572 surrounds each sintering interface region 575, 576, 577 and the power modules 580 sintered thereto.

For example, each sintering interface region 575, 576, 577 may be formed separately on the cold plate 570, and then the electrical insulation region 572 may be attached to the cold plate 570. In another example, the electrical insulation region 572 may be attached to the cold plate 570, and then the sintering interface material may be applied to each sintering interface region 575, 576, 577.

FIGS. 7B and 7D present a left side view and a perspective left side view (respectively) of the cold plate 570 of the traction inverter 500, in accordance with embodiments of the present disclosure.

In certain embodiments, the cold plate 570 includes pin fins 590 extending from a second side 579. The pins fins 590 transfer additional heat from the cold plate 570 to the cooling fluid as compared to a bare surface. The pin fins 590 may be arranged into pin fin regions 595, 596, 597, and each pin fin region 595, 596, 597 may correspond to one of the sintering interface regions 575, 576, 577.

For example, the pin fin region 595 may be disposed opposite to the sintering interface region 575, the pin fin region 596 may be disposed opposite to the sintering interface region 576, and the pin fin region 597 may be disposed opposite to the sintering interface region 577.The many features and advantages of the disclosure are apparent from the detailed specification, and, thus, it is intended by the appended claims to cover all such features and advantages of the disclosure which fall within the scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

What is claimed is:

1. A traction inverter system, comprising:
a chassis configured to be attached to a housing of an electric motor with a rotational axis;
a cold plate attached to the chassis, the cold plate comprising a first side and a second side, the first side comprising one or more sintering interface regions;
power modules sintered to the sintering interface regions, the power modules coupled to the electric motor; and
a cover attached to a perimeter of the chassis,
wherein the rotational axis is perpendicular to a plane defined by the perimeter of the chassis.

2. The traction inverter system of claim 1, further comprising:
an electrical insulation region disposed on the first side of the cold plate,
wherein the electrical insulation region surrounds each sintering interface region.

3. The traction inverter system of claim 2, wherein the cold plate further comprises pin fins extending from the second side.

4. The traction inverter system of claim 3, wherein:
the pin fins are arranged into pin fin regions; and
each pin fin region corresponds to one of the sintering interface regions.

5. The traction inverter system of claim 4, wherein:
the electric motor is a three phase alternating current (AC) electric motor;
the sintering interface regions include three sintering interface regions; and
the power modules include three power modules, and each power module generates one phase of AC power provided to the three phase AC electric motor.

6. The traction inverter system of claim 5, further comprising a capacitor module coupled to a high voltage (HV) battery cable and the power modules.

7. The traction inverter system of claim 5, further comprising an AC busbar attached to the chassis, the AC busbar configured to couple the power modules to the three phase AC electric motor.

8. The traction inverter system of claim 5, further comprising a controller board attached to the chassis, the controller board comprising at least one processor coupled to the power modules, the processor configured to control the power modules to generate the AC power for the three phase AC electric motor.

9. The traction inverter system of claim 1, further comprising:
a gasket disposed along the perimeter between the chassis and the cover,
wherein the chassis and the cover form an enclosed volume that is sealed by the gasket.

10. The traction inverter system of claim 1, wherein:
the chassis has a first dimension along a first axis, a second dimension along a second axis, and a third dimension along a third axis;
the first axis, the second axis, and the third axis are orthogonal;
the first axis and the second axis define the plane;
the third axis is parallel to the rotational axis; and
the third dimension is less than the first dimension, and less than the second dimension.

11. An electric drive unit (EDU) for an electric vehicle, comprising:
an electric motor comprising:
a housing, and
an alternating current (AC) electric motor with a rotational axis; and
a traction inverter system comprising:
a chassis attached to the housing of the electric motor,
a cold plate attached to the chassis, the cold plate comprising a first side and a second side, the first side comprising one or more sintering interface regions,
power modules sintered to the sintering interface regions, the power modules coupled to the AC electric motor, and
a cover attached to a perimeter of the chassis,
wherein the rotational axis is perpendicular to a plane defined by the perimeter of the chassis.

12. The EDU of claim 11, wherein:
the traction inverter system further comprises an electrical insulation region disposed on the first side of the cold plate; and
the electrical insulation region surrounds each sintering interface region.

13. The EDU of claim 12, wherein the cold plate further comprises pin fins extending from the second side.

14. The EDU of claim 13, wherein:
the pin fins are arranged into pin fin regions; and
each pin fin region corresponds to one of the sintering interface regions.

15. The EDU of claim 14, wherein:
the electric motor is a three phase AC electric motor;
the sintering interface regions include three sintering interface regions; and
the power modules include three power modules, and each power module generates one phase of AC power provided to the three phase AC electric motor.

16. The EDU of claim 15, wherein the traction inverter system further comprises a capacitor module coupled to a high voltage (HV) battery cable and the power modules.

17. The EDU of claim 15, wherein:
the traction inverter system further comprises an AC busbar attached to the chassis; and
the AC busbar is configured to couple the power modules to the three phase AC electric motor.

18. The EDU of claim 15, wherein:
the traction inverter system further comprises a controller board attached to the chassis;
the controller board comprises at least one processor coupled to the power modules; and
the processor is configured to control the power modules to generate the AC power for the three phase AC electric motor.

19. The EDU of claim 11, wherein:
the traction inverter system further comprises a gasket disposed along the perimeter between the chassis and the cover; and
the chassis and the cover form an enclosed volume that is sealed by the gasket.

20. The EDU of claim 11, further comprising a gearbox attached to the electric motor.
